(19) United States
(12) Patent Application Publication
(10) Pub. No.: US 2013/0257469 A1
(43) Pub. Date: Oct. 3, 2013

(54) CURRENT SENSOR

(71) Applicant: ALPS GREEN DEVICES CO., LTD., Tokyo (JP)

(72) Inventor: Masahito ARIMA, Miyagi-ken (JP)

(73) Assignee: ALPS GREEN DEVICES CO., LTD., Tokyo (JP)

(21) Appl. No.: 13/769,163

(22) Filed: Feb. 15, 2013

(30) Foreign Application Priority Data
Mar. 29, 2012 (JP) 2012-077783
Jul. 6, 2012 (JP) 2012-152483

(51) Int. Cl. G01R 1/04

(52) U.S. Cl. CPC G01R 1/0408
USPC 324/756.01

(57) ABSTRACT

A current sensor including electromagnetic conversion elements to detect magnetic fields generated when current flows through a current path under test, a chassis that stores the electromagnetic conversion elements and includes a channel to which the current path under test is disposed, and an installation member securable to the chassis, with the installation member including two arm units and a connecting unit to movably connect each end of the two arms, in which hook units are provisioned on the outer side of the two arm units, and holes are provisioned on the channel of the chassis to engaged with the hook units of the installation member, and when the current path under test and the installation member is disposed in the channel, the current path under test is securely supported, and at the same time the hook units and the holes are engaged.

### CLAIM OF PRIORITY

This application claims benefit of Japanese Patent Application No. 2012-077783 filed on Mar. 29, 2012 and No. 2012-152483 filed on Jul. 6, 2012, which are hereby incorporated by reference.

### BACKGROUND OF THE INVENTION

1. Field of the Invention

The present invention relates to a current sensor that detects current flowing in a current path under test.

2. Description of the Related Art

It is well known to install current sensors downstream in an existing current path under test to control and monitor various devices. It is known to use magnetic sensors that use coils that detect magnetic fields generated from the current flowing in the current path under test, or that use electron hole elements or other types of electromagnetic conversion elements as this type of current sensor.

As an example of the related art, Japanese Unexamined Patent Application Publication No. 2002-228700 proposes a disconnect detection device that includes a detection unit 803 arranged with multiple electron hole elements 809 in which a current sensor is installed downstream in existing wiring under test (current path under test). FIG. 14 is cross-sectional diagram illustrating an example of the detection unit 803 of the disconnect detection device in Japanese Unexamined Patent Application Publication No. 2002-228700. As illustrated in FIG. 14, the detection unit 803 is configured with a hinge unit 808 that is connected to a guide rail to move the detection unit 803 along the side of the wiring under test, a pair of semicircular units 812 (812A and 812B) that may divide a division face 813, and multiple electron hole elements 809 (four in FIG. 14) arranged in the pair of semicircular units 812. Also, by dividing the pair of semicircular units 812, the existing wiring under test (not illustrated in FIG. 14) is passed through a hollow unit 814, formed by the pair of semicircular units 812 forming a circular shape, and so this detection unit 803 may detect disconnections for the wiring under test.

However, according to Japanese Unexamined Patent Application Publication No. 2002-228700, no method to secure the wiring under test when installing the existing wiring under test to the detection unit 803 that includes multiple electron hole elements 809 is disclosed, and so there is some concern that the positional relationship between the multiple electron hole elements 809 and the wiring under test could become misaligned. When performing current measurement of the existing wiring under test using multiple magnetic sensors (electron hole elements 809) with such a configuration, and if the position of each magnetic sensor from the wiring under test is misaligned, however small, this produces a large effect on accuracy of measurement, which has resulted in unsatisfactory measurement accuracy, and so such a device has only been used for in cases of disconnection detection that did not demand measurement accuracy.

Japanese Unexamined Patent Application Publication No. 11-251167 proposes a through-type current detection device 900 that has the ability to secure a power wiring (the current path under test) 917. FIGS. 15A and 15B are diagrams illustrating an example of the through-type current detection device 900 from Japanese Unexamined Patent Application Publication No. 11-251167, where FIG. 15A is a perspective view of the through-type current detection device 900, and FIG. 15B is a exploded perspective view of the through-type current detection device 900. As illustrated in FIGS. 15A and 15B, the through-type current detection device 900 is mainly configured with a case 901A that houses two lower cores, a lower core 905A and a lower core 905B, a printed circuit board 906, and an electron hole element 907, an upper cover 912 that houses an upper core 904, a lower core holder 902A that holds the lower core 905A and 905B, and an upper core holder 903A to hold the upper core 904. Also, when the upper cover 912 covers the case 901A, a groove portion 902A of the lower core holder 902A and a groove portion 903A of the upper core holder 903A form a cylindrical space, and the power wiring 917 is inserted in this space. Further, the power wiring 917 is secured by fitting a hook 909B on the right side of the case 901A to a window 913A formed in a knob 913.

### SUMMARY OF THE INVENTION

Although according to Japanese Unexamined Patent Application Publication No. 11-251167, installation of the through-type current detection device 900 to the wiring 917 is simple and can be accomplished in a short amount of time, there is still a problem in which the wiring 917 may not be reliably secured in a desired position. For example, when a load is added to the wiring 917, the fitting between the window 913A and the hook 909B is readily removed, and the through-type current detection device 900 may be removed from the power wiring 917. Also, the configuration does not have the wiring 917 tightly sandwiched between the groove portion 902A and the groove portion 903A, which creates a potential for the wiring 917 to become loose, and so the positional relationship between the electron hole elements 907 and the wiring 917 may become misaligned. According to Japanese Unexamined Patent Application Publication No. 11-251167, the magnetic flux of the wiring 917 is converged using the upper core 904 and the lower cores 905A and 905B to perform detection at the electron hole element 907, and so while a certain amount of positional misalignment is allowed, particularly in a case such as in Japanese Unexamined Patent Application Publication No. 2002-228700 in which a core is not used, misalignment between the positions of the magnetic sensor and the wiring under test, however small, produces a large effect on accuracy of measurement, and this has resulted in unsatisfactory measurement accuracy.

The present invention provides a current sensor in which the current path under test is reliably secured in a desired position, which resolved the problems previously described.

The current sensor of the present invention is provisioned with electromagnetic conversion elements to detect a magnetic field generated when current flows through a current path under test, a chassis to store the electromagnetic conversion elements, and an installation member installed in an established channel in the chassis, in which the installation member includes two arm units installed with hook units that protrude toward the interior wall formed from the channel, and a connecting unit to connect each end of the two arms, in which the interior wall that forms the channel is provisioned with holes to engage the hook units, and so the current path under test is arranged inside the installation member.

With such a configuration, when the current path under test and the installation member is disposed in the channel of the chassis, the current path under test is secured in the channel of the chassis, and at the same time, the hook units provisioned on the arms units of the installation member are engaged in the holes provisioned in the interior wall that forms the channel, and so if the current path under test and the installation member might be removed from the channel, the engagement between the hook units and the holes prevents this movement. As a result, by inserting the current path under test and the installation member into the channel of the chassis, the current path under test may readily be disposed in a desired position, and the current path under test is also reliably secured. Therefore, a current sensor may be provided in which the current path under test is reliably secured in a desirable position.

Also, according to the current sensor of the present invention, the installation member may be flexed to an interior side at a state when holding the current path under test is held by the two arm units and the inner side of the connection unit.

With such a configuration, as the installation member may be flexed to an interior side at a state when holding the current path under test is held by the two arm units and the inner side of the connection unit, the installation and removal of the installation member to/from the chassis may be readily performed. That is to say, the installation member is inserted in the channel at a state where the two arm units are flexed to the inner side, and the flexure of each arm unit is released at the position where the hook units and the holes engage, which enables the installation member to be installed to the chassis. For this reason, the current path under test is held by the internal portion furthest away from the external side of the chassis, and so in the event some force is applied externally to the chassis, the current path under test is not readily removed to the external side of the chassis, and the current path under test may be reliably secured. In contrast, the installation member may be removed from the chassis by flexing the two arm units internally, and disengaging the hook units from the holes, which allows the installation member to be readily removed from the channel to the external side of the chassis.

Also, the interior wall of the installation member, which includes the connection unit, may be formed as a curved wall that spans at least 180° corresponding to the outer edge of the cylindrically shaped current path under test.

With such a configuration, as the interior wall is formed as a curved wall that spans at least 180° corresponding to the outer edge of the cylindrically shaped current path under test, after widening the two arm units of the installation member and disposing the current path under test in the portion enclosed in the curved wall, the current path under test is held in the curved wall that spans at least 180°. For this reason, when arranging the installation member onto the chassis at this state, the two arm units are constrained by the interior surface that forms the channel of the chassis, and so it is difficult for the current path under test to be come loose from the portion enclosed in the curved wall. As a result, the current path under test may be disposed in a desirable position and more reliably secured, which is achieved with a simple configuration.

Also, the interior wall of the installation member, which includes the connection unit, may be formed having a form complementary to the outer circumference form of the current path under test having a rectangular cross-section form.

With such a configuration, as the interior wall of the installation member, which includes the connection unit, is formed having a form complementary to the outer circumference form of the current path under test having a rectangular cross-section form, the current path under test having a rectangular cross-section form is reliably secured at a state where the interior wall abuts (touches) contiguously corresponding to the outer circumference of the current path under test over a wide area.

Also, a depression unit may be formed on the connection unit of the interior wall of the installation member.

With such a configuration, the depression unit formed in the connection unit of the interior wall of the installation member acts as a buffer portion, which is readily deformed, and so the installation member may be readily removed from the chassis by flexing each arm unit and disengaging the hook units from the holes.

Also, a flange portion may be provisioned to clamp the chassis to the connection unit.

With such a configuration, the flange portion that is provisioned on the connection unit to clamp the chassis prevents vertical movement of the installation member regarding the chassis. As a result, this prevents the installation member from being removed from the channel in the chassis. Further, minimizing the gap between the flange portion and the chassis prevents the installation member from vibrating.

Also, a notch may be provisioned in the flange portion.

With such a configuration, as a notch is provisioned in the flange portion, this notch acts as a buffer portion, and so the flange portion is readily deformed. As a result, the arm units of the installation member are readily opened, and the current path under test is readily disposed in the portion enclosed in the curved wall.

Also, the current path under test may be held by being sandwiched between the interior wall surface of the channel and the exterior wall surface of the connection unit.

With such a configuration, as the current path under test is held by being sandwiched between the interior wall surface of the channel and the exterior wall surface of the connection unit, the current path under test is reliably held.

Also, the interior wall surface of the chassis that forms the bottom of the channel may be formed as a curved surface, and the exterior wall surface of the connection unit of the installation member is also formed as a curved surface, and when the installation member is disposed in the channel of the chassis, and the hook units are engaged in the holes, a circular space is formed between the interior wall surface and the exterior wall surface.

With such a configuration, a circular space is formed between the interior wall surface of the chassis that forms the bottom of the channel and the exterior wall surface of the connection unit of the installation member, and so the current path under test is disposed in this space. For this reason, the current path under test may be sandwiched between the interior wall surface and the exterior wall surface, and when the installation member is disposed in the chassis, it is difficult to remove the current path under test, via the installation member, from the channel portion of the chassis. As a result, the current path under test may be disposed in a desirable position and more reliably secured, which is achieved with a simple configuration. Particularly, when the current path under test has a circular form, the outer edge of the current path under test is held by the interior wall surface and the exterior wall surface, which are curved surfaces, and so the current path under test may be disposed in a more desirable position. Here, the bottom of the channel is the portion of the interior wall surface that forms the channel that is in the most interior position, and represents the interior wall surface that meets the distal portion of the installation member that is inserted into the channel

Also, when the installation member is disposed in the channel of the chassis, and the hook units are engaged in the holes, a portion of the two arm units may protrude from the chassis.

With such a configuration, when the installation member is disposed in the channel of the chassis, and the hook units are engaged in the holes, and a portion of the two arm units protrude from the chassis, by moving the two arm units to the inner side to remove the hook units from the holes, the hook units may be disengaged from the holes. As a result, so the installation member can be detached from the channel of the chassis, and the current path under test can be easily removed, which is achieved with a simple configuration.

Also, when the current path under test is disposed in the channel, multiple electromagnetic conversion elements may be arranged above a virtual ellipse centered around the current path under test.

With such a configuration, as multiple electromagnetic conversion elements are arranged on the virtual ellipse centered around the current path under test, the detection values from each electromagnetic conversion element may be added together. As a result, a small misalignment of the position of the current path under test is unlikely to decrease measurement accuracy.

### BRIEF DESCRIPTION OF THE DRAWINGS

FIG. 1 is an exploded perspective view of a current sensor related to a first Embodiment of the present invention.

FIGS. 2A and 2B are diagrams describing the current sensor related to the first Embodiment, in which FIG. 2A is a front view diagram seen from the Y2 side illustrated in FIG. 1, and FIG. 2B is the front view diagram illustrated in FIG. 2A with a cover removed.

FIGS. 3A and 3B are diagrams describing the current sensor related to the first Embodiment, in which FIG. 3A is a side view diagram seen from the X1 side illustrated in FIG. 1, and FIG. 3B is a bottom view diagram seen from the Z2 side illustrated in FIG. 1.

FIGS. 4A and 4B are diagrams describing a chassis of the current sensor related to the first Embodiment, in which both FIGS. 4A and 4B are perspective view diagrams of the chassis seen at different angles.

FIGS. 5A through 5C are diagrams describing the current sensor related to the first Embodiment, in which FIG. 5A is a front view diagram of an installation member seen from the Y2 side illustrated in FIG. 1, and FIGS. 5B and 5C are perspective view diagrams of the installation member seen at different angles.

FIG. 6 is an exploded perspective view illustrating the current sensor related to a second Embodiment of the present invention.

FIGS. 7A and 7B are diagrams describing the current sensor related to the second Embodiment, in which FIG. 7A is a front view diagram seen from the Y2 side illustrated in FIG. 6, and FIG. 7B is the front view diagram illustrated in FIG. 7A with the cover removed.

FIGS. 8A and 8B are diagrams describing the current sensor related to the second Embodiment, in which FIG. 8A is a side view diagram seen from the X1 side illustrated in FIG. 6, and FIG. 8B is a bottom view diagram seen from the Z2 side illustrated in FIG. 6.

FIGS. 9A and 9B are diagrams describing a chassis of the current sensor related to the second Embodiment, in which both FIGS. 9A and 9B are perspective view diagrams of the chassis seen at different angles.

FIGS. 10A through 10C are diagrams describing an installation member of the current sensor related to the second Embodiment, in which FIG. 10A is a front view diagram of an installation member seen from the Y2 side illustrated in FIG. 6, and FIGS. 10B and 10C are perspective view diagrams of the installation member seen at different angles.

FIG. 11 is a diagram that describes a first Modification of the current sensor related to the first Embodiment, and is a front view diagram of the current sensor.

FIGS. 12A and 12B are front view diagrams describing a second Modification of the current sensor related to the first Embodiment in which FIG. 12A is a front view diagram seen from the Y2 side illustrated in FIG. 1, and FIG. 12B is the front view diagram illustrated in FIG. 12A with the cover removed.

FIGS. 13A through 13C are diagrams describing the installation member of the current sensor related to the second Modification, in which FIG. 13A is a front view diagram seen from the Y2 side illustrated in FIG. 1, and FIGS. 13B and FIG. 13C are perspective view diagrams of the installation member seen at different angles.

FIG. 14 is a cross-sectional diagram illustrating an example detection unit of a disconnect detection device related to Japanese Unexamined Patent Application Publication No. 2002-228700.

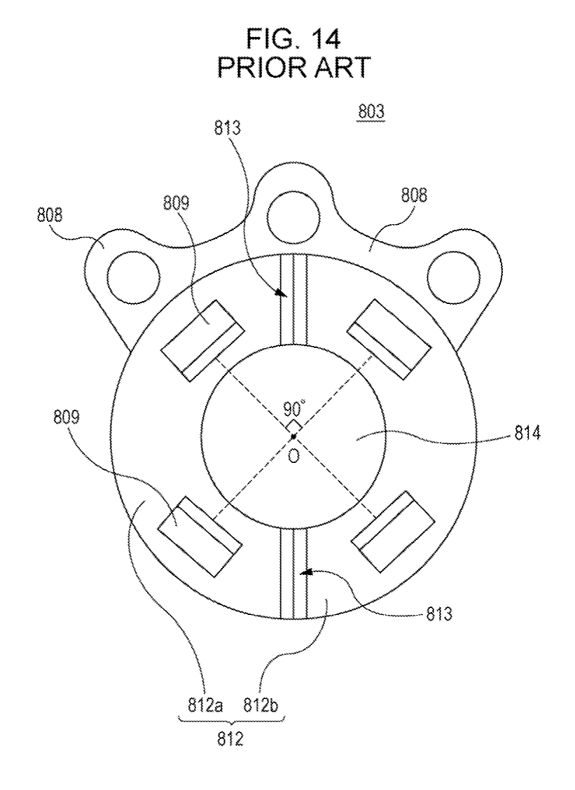

FIGS. 15A and 15B are diagrams illustrating an example of a through-type current detection device related to Japanese Unexamined Patent Application Publication No. 11-251167, in which FIG. 15A is a perspective diagram of the through-type current detection device, and FIG. 15B is an exploded perspective view of the through-type current detection device.

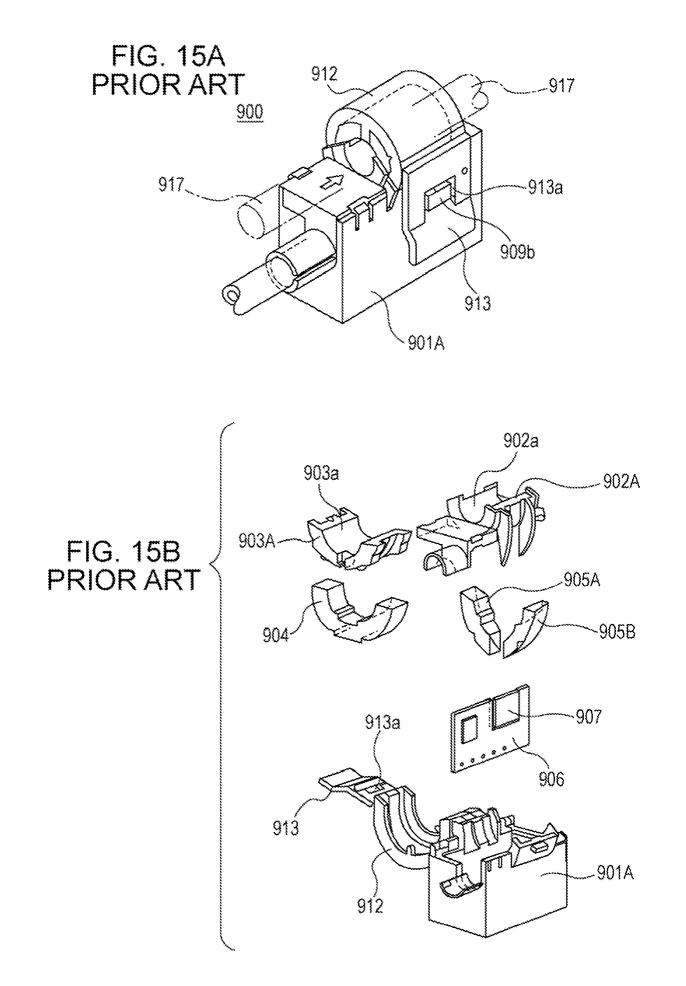

### DESCRIPTION OF THE PREFERRED EMBODIMENTS

The embodiments of the present invention will be described below with reference to the drawings.

### First Embodiment

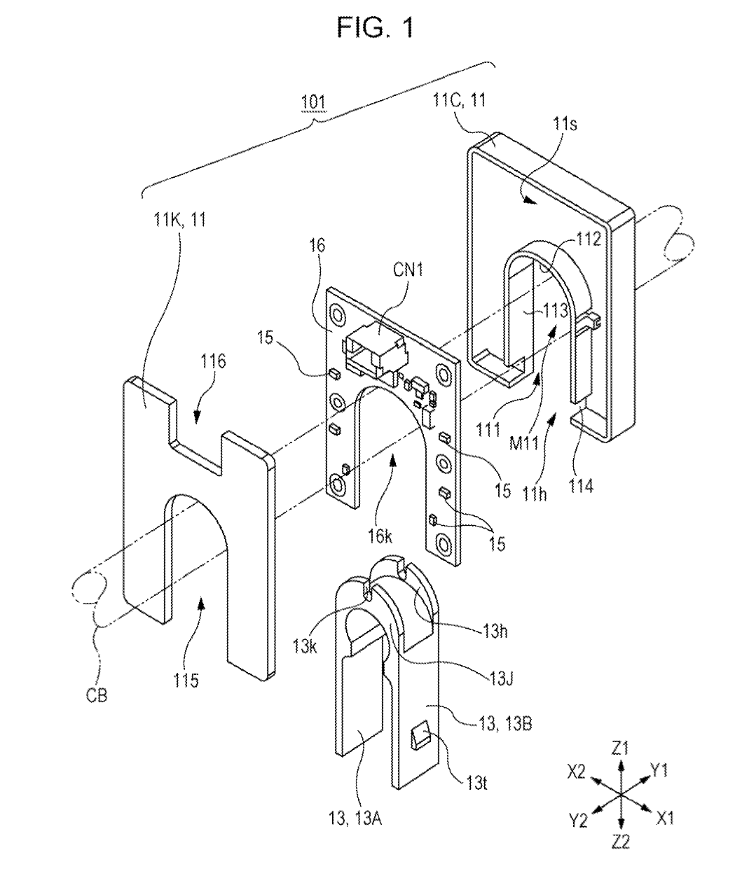

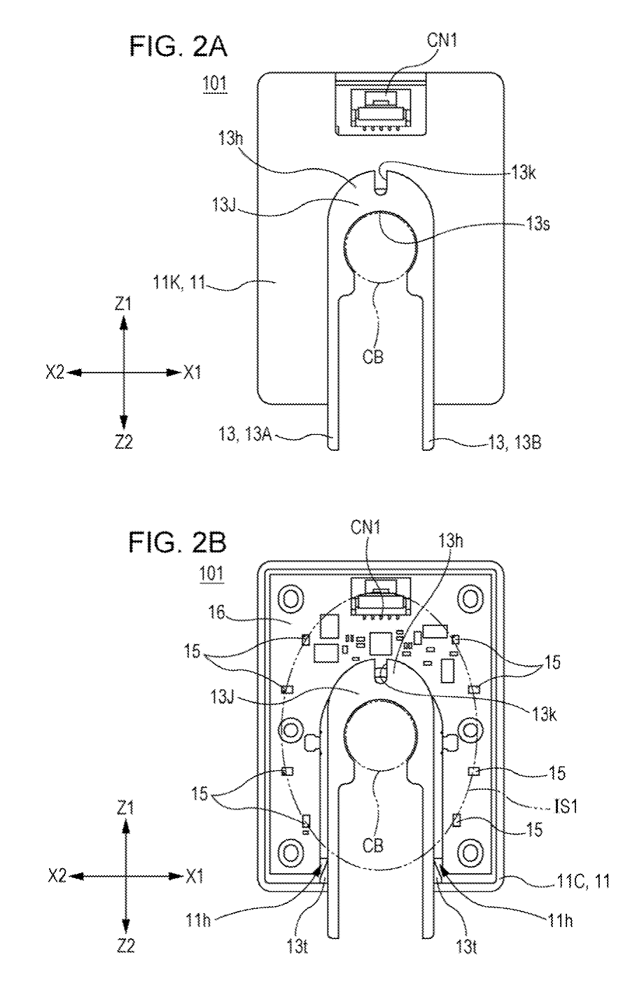

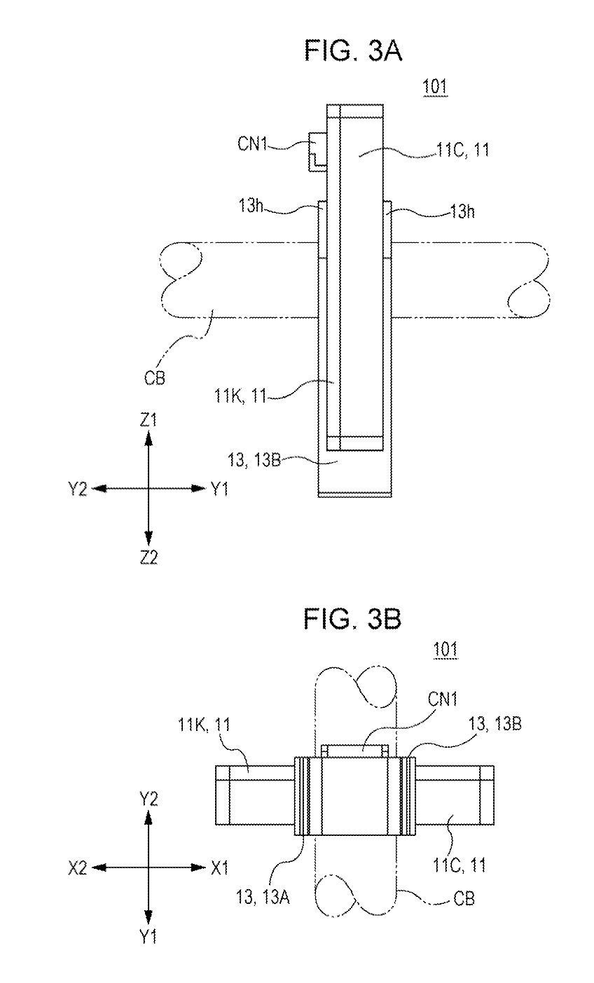

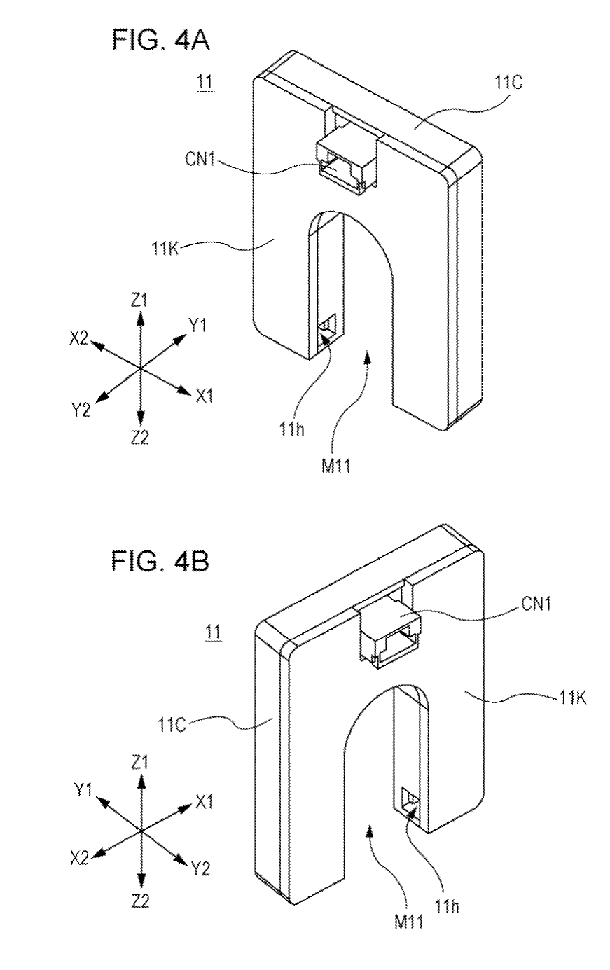

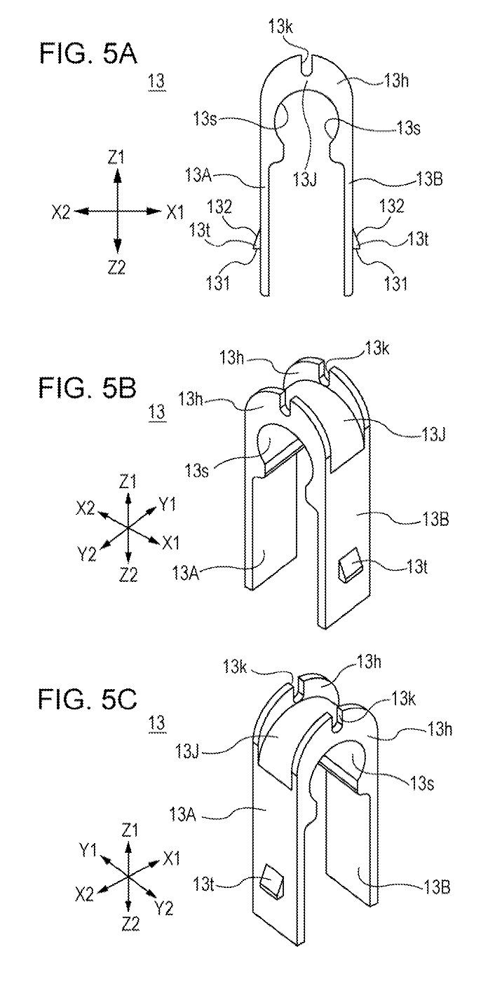

FIG. 1 is an exploded perspective view of a current sensor 101 related to a first Embodiment of the present invention. FIGS. 2A and 2B are diagrams describing the current sensor 101 related to the first Embodiment, in which FIG. 2A is a front view diagram seen from the Y2 side illustrated in FIG. 1, and FIG. 2B is the front view diagram illustrated in FIG. 2A with a cover 11K removed. FIGS. 3A and 3B are diagrams describing the current sensor 101 related to the first Embodiment, in which FIG. 3A is a side view diagram seen from the X1 side illustrated in FIG. 1, and FIG. 3B is a bottom view diagram seen from the Z2 side illustrated in FIG. 1. FIGS. 4A and 4B are diagrams describing a chassis 11 of the current sensor related to the first Embodiment, in which both FIGS. 4A and 4B are perspective view diagrams of the chassis 11 seen at different angles. FIGS. 5A through 5C are diagrams describing an installation member 13 of the current sensor related to the first Embodiment, in which FIG. 5A is a front view diagram of the installation member 13 seen from the Y2 side illustrated in FIG. 1, and FIGS. 5B and 5C are perspective view diagrams of the installation member 13 seen at different angles.

As illustrated in FIG. 1 through 3B, the current sensor 101 is configured with multiple electromagnetic conversion elements 15 to detect magnetic fields generated when current flows through a current path under test CB, the chassis 11 which includes a channel M11 disposed with the current path under test CB, and the installation member 13 that may be secured to the chassis 11. Also, the current sensor 101 is provisioned with a wiring board 16 stored in a storage unit 11S of the chassis 11, and a connector CN1 that includes an extraction terminal (not illustrated) to extract electrical signals from the electromagnetic conversion elements 15 installed on the wiring board 16.

As illustrated in FIGS. 1, 2A, 2B, 4A, and 4B, the chassis 11 is configured with a case 11C formed as a box with an opening on one side that stores the wiring board 16 to which the multiple electromagnetic conversion elements 15 are installed, and a cover 11K to cover the case 11C on the opening side. The channel M11 in the chassis 11 is formed in a U-shape (concave form) such that the chassis 11 is cut from one end toward the center. The channel M11 is configured to be disposed with the installation member 13 and the current path under test CB. Also, the interior surface (inner circumference surface) of the chassis 11, which forms the channel M11, is provisioned with a hole 11h on each right and left side to engage hook units 13t of the installation member 13, which is described later.

The chassis 11 may be formed using synthetic plastic materials such as ABS (acrylonitrile butadiene styrene), PET (polyethylene terephthalate), PBT (polybutylene terephthalate), or LCP (liquid crystal polymer). Use of synthetic plastic materials enables the chassis 11 to be readily manufactured by injection molding or other technique.

The case 11C is formed as a box with an opening on one side, and also with a storage unit 11S that may internally store the wiring board 16. Also, a depression unit 111 is formed by cutting the case 11C from one end toward the center. This depression unit 111 is formed at a size large enough to store the installation member 13, and is also formed having a form complementary to the outer shell of the installation member 13. According to the present embodiment, a rearward wall 112 of the depression unit 111 is formed with a curve that corresponds to the form of the outer circumference surface of a connection unit 13J of the installation member 13. Also, an interior wall 113 connected to both ends of the rearward wall 112 is formed in parallel separated with just enough distance to store a pair of arms units 13A and 13B of the installation member 13. A pair of notches 114 for installing the installation member 13 is formed in each interior wall 113 at a position so that they are facing each other. Each notch 114 is provisioned near the entrance of the depression unit 111, and is formed so that the case 11C is cut vertically from the opening of the case 11C toward the direction of the storage surface side of the storage unit 11S (bottom portion). According to the present embodiment, each notch 114 is formed in a side flange form at opposing positions that connects to the outer wall of the entrance point. This notch 114 configures the hole 11h previously described by closing the opening of the case 11C with the cover 11K.

The cover 11K is formed with laminate materials, and a depression unit 115 is formed on one edge with the same form as that of the depression unit 111 of the case 11C. That is to say, the depression unit 115 of the cover 11K is similar to the depression unit 111 of the case 11C in that it is formed at a size large enough to store the installation member 13, and is also formed having a form complementary to the outer shell of the installation member 13. The depression unit 115 formed in this cover 11K and the depression unit 111 of the same form formed in the case 11C together form the channel M11 previously described. Also, an opening 116 is formed on the edge formed by the depression unit 115 of the cover 11K and the edge on the opposing side to expose a portion of a connector CN1 externally from the chassis 11.

The wiring board 16 may be formed, for example, using a generally well-known double-sided printed wiring board, in which copper (Cu) or some other metallic foil is patterned on the base board, which is formed from glass mixed with epoxy resin, to form the wiring pattern. The wiring board 16 is formed having a form complementary to the storage surface (bottom surface) of the storage unit 11S, and a notch 16K is formed having a form complementary to the depression unit 111 of the case 11C. The interior wall 113 of the case 11C previously described is sandwiched in this notch 16K, and the current path under test CB is inserted here. As illustrated in FIG. 1 and FIG. 2B, multiple electromagnetic conversion elements 15 (8 in FIG. 2B) are installed (situated) near the notch 16K of the wiring board 16. According to the present embodiment, a printed wiring board formed from glass mixed with epoxy resin is used, but this is not specifically limited, and so a rigid board with insulating properties may be used, for example, or a ceramic wiring board may also be used.

The electromagnetic conversion element 15 is a current sensor element that detects magnetic fields generated when current flows through the current path under test CB, and may use, for example, a magnetic detection element that has a giant magneto resistive (hereinafter may be referred to as “GMR”) property. Though details are not illustrated for simplification of the description, this electromagnetic conversion element 15 is configured by manufacturing the GMR element onto a silicon substrate, and then using thermoset synthetic plastic to package the chip that has been cut out, and a lead terminal to extract signals is electrically connected to the GMR element. Also, the device is then soldered to the wiring board 16 by this lead terminal.

As illustrated in FIG. 1 and FIG. 2B, the eight units of the electromagnetic conversion element 15 are disposed by being sandwiched between the wiring board 16 and the notch 16K. According to the present embodiment and as illustrated in FIG. 2B, when the current path under test CB is disposed in the channel M11 of the chassis 11 discussed later, the eight units of the electromagnetic conversion element 15 are disposed on a virtual ellipse IS1 centered around the current path under test CB. As a result, the detection values from each electromagnetic conversion element 15 may be added together, and so a small misalignment of the position of the current path under test CB is unlikely to decrease measurement accuracy.

As illustrated in FIG. 1 through FIG. 5C, the installation member 13 is configured with two arm units 13A and 13B, and a connection unit 13J that connects and supports movement of the two arm units 13A and 13B. Specifically, the installation member 13 is formed roughly in a U shape, and is configured with a pair of arm units 13A and 13B formed as long plates, and the connection unit 13J to which a portion of each arm unit 13A and 13B is connected. The current path under test CB is inserted in this installation member 13 from the free edge side (other end) of the arms units 13A and 13B between the arms units 13A and 13B, and the current path under test CB is disposed near the interior wall of the connection unit 13J. Also, the installation member 13 is formed at a size large enough to be inserted in the channel M11 of the chassis 11, and this outer shell form is also formed having a form complementary to the inner circumference of the channel M11 (in other words, the inner circumference of the depression unit 111 of the case 11C and the depression unit 115 of the cover 11K). This installation member 13 is formed using synthetic plastic materials such as ABS (acrylonitrile butadiene styrene), PET (polyethylene terephthalate), PBT (polybutylene terephthalate), LCP (liquid crystal polymer), or the like, in the same way as with the chassis 11. Use of synthetic plastic materials enables the installation member 13 to be readily manufactured by injection molding or other technique.

The pair of arm units 13A and 13B extend in parallel from both ends of the connection unit 13J. Specifically, the connecting portions of the arms units 13A and 13B and the connection unit 13J are configured with a curvature that allows the arm units 13A and 13B to flex in an opposing direction that creates enough space for the current path under test CB to enter and pass through the channel M11 toward the installation member 13. Also as illustrated in FIGS. 1, 2B, 5A, 5B, and 5C, the hook unit 13t is formed on the outer side of both arms units 13A and 13B. Specifically, the hook unit 13t is formed on the outer surface of each arm unit 13A and 13B, and protrudes outward. As previously described, this pair of hook units 13t is configured to engage with each hole 11h provisioned on the interior surface (interior wall 113) of the chassis 11 that forms the channel M11. Regarding the outer surface of the arm units 13A and 13B, each hook unit 13t is formed at a position so that the free end side of the arms units 13A and 13B are exposed externally from the chassis 11 when installed to the chassis 11. The exposed portions of the arm units 13A and 13B are used to install and remove the current path under test CB to/from the installation member 13, and to install and remove the installation member 13 to/from the chassis 11. Also, each hook unit 13t is formed to extend outward toward the free end side of the arm units 13A and 13B, and is configured with an abutment surface 131 that extends vertically regarding the formed surface of the hook unit 13t of the arms units 13A and 13B, and a diagonal surface 132 that connects with this abutment surface 131 (refer to FIG. 5A). This abutment surface 131 of the hook unit 13t secures the installation member 13 to the chassis 11 by the abutment to the entrance end face of the notch 114 formed on the interior wall 113 of the case 11C (for the present embodiment, this is the outer wall of the entrance side), at a state positioned in the direction of the formed channel M11 (Z axis illustrated in FIGS. 1, 2A, and 2B).

Also as illustrated in FIGS. 5A, 5B, and 5C, the interior wall of the installation member 13 including the connection unit 13J is formed as a curved wall 13S that spans at least 180°. The current path under test CB is disposed in the space formed within this curved wall 13S. When the current path under test CB is cylindrical in form, this curved wall 13S is curved corresponding to the outer edge of the current path under test CB. That is to say, the curved wall 13S is formed having a form complementary to the form of the outer circumference of the current path under test CB (cross-sectional form) held in a holding space, at a state in which the insertion entrance (and exit) points regarding the space (holding space) for the current path under test CB are secured. The curved wall 13S is formed so that the thickness of the interior wall of the installation member 13 near the connection unit 13J corresponds to the outer circumference of the current path under test CB by forming this thickness thicker than the free end side of the arm units 13A and 13B to conform to the form of the outer circumference of the current path under test CB. As a result, the current path under test CB is held at a state where the curved wall 13S abuts (touches) contiguously corresponding to the outer circumference of the current path under test CB over a wide range.

Also, the curved wall 13S is formed so that the entrance (and exit) points for the holding space of the current path under test CB are slightly narrower than the maximum diameter of the holding space. As previously described, the connecting portions of the arms units 13A and 13B and the connection unit 13J are configured with a curvature that allows the arm units 13A and 13B to flex in an opposing direction that creates enough space for the current path under test CB to enter and pass through the channel M11 toward the installation member 13. Therefore, when disposing the current path under test CB within the holding space of the curved wall 13S, the current path under test CB is readily inserted in the holding space by pushing open the arm units 13A and 13B so as to separate them wide enough so that the entrance of the holding space allows the maximum diameter portion of the current path under test CB to pass through. After the current path under test CB is inserted in the holding space, the arm units 13A and 13B return to their initial state parallel to each other, and the entrance of the holding space returns to a state just narrower than the maximum diameter of the holding space. As a result, the current path under test CB inserted from the entrance point is not easily removed from the holding space. Further, by adjusting the thickness of the interior wall, the curved wall 13S may be formed to correspond to a current path under test CB that has different diameter dimensions.

Also as illustrated in FIG. 1 through FIG. 5C, a flange portion 13h is provisioned on the installation member 13 that extends in the direction along the chassis 11 (Z1 axis illustrated in FIG. 3A) from each side edge of the connection unit 13J. That is to say, a pair of the flange portions 13h are formed on the outer circumference edge of the connection unit 13J separated to deeply sandwich the portion near the rearward wall 13J of the channel M11 of the chassis 11. When disposing the installation member 13 in the channel M11 of the chassis 11, the chassis 11 is sandwiched by the pair of flange portions 13h, and so the installation member 13 is positioned deep in the chassis 11. Each flange portion 13h is formed along the outer circumference edge of the connection unit 13J, and a notch 13K is formed in the center portion of the flange portion 13h.

The following describes an example procedure (method) to install and remove the current sensor 101 configured as previously described to/from the current path under test CB.

First, the arm units 13A and 13B on the left and right side of the installation member 13 are pushed open until the entrance point of the holding space of the installation member 13 is wide enough for the portion of the current path under test CB at its maximum diameter may pass through. Next, the current path under test CB is inserted between the arm units 13A and 13B from the free edge side of each arm unit 13A and 13B, and then through the entrance point of the holding space to be disposed in the cylindrical holding space of the installation member 13. At this time, the connecting portions of the arms units 13A and 13B and the connection unit 13J are curved to allow the arm units 13A and 13B to flex in an opposing direction that creates enough space for the current path under test CB to readily enter. Also, the notch 13K is formed in the flange portion 13h, which acts as the buffer portion, and so the shape of the flange portion 13h is readily deformed. As a result, the pair of arm units 13A and 13B may be readily opened, and the current path under test CB may be readily enclosed in the portion of the curved wall 13S (holding space). Also, after the current path under test CB is inserted into the holding space, the arm units 13A and 13B return to their parallel state, and the entrance point of the holding space returns to a state slightly narrower than the maximum diameter of the holding space. At this time, the current path under test CB in the holding space is held by the curved wall 13S that spans at least 180°. That is to say, the curved wall 13S is formed having a form complementary to the outer circumference of the current path under test CB, and so the current path under test CB is held at a state where the curved wall 13S abuts contiguously corresponding to the outer circumference of the current path under test CB. Also, as the entrance point of the holding space is slightly narrower than the maximum diameter of the holding space, the current path under test CB inserted from the entrance point is not easily removed from the holding space, and may be reliably secured in the holding space.

Next, the channel M11 of the chassis 11 and the connection unit 13J of the installation member 13 are set to face each other, and as the installation member 13 is slid relative to the chassis 11, the installation member 13 is installed so that it fits into the channel M11 of the chassis 11. At this time, each flange portion 13h of the installation member 13 is positioned to the outer side of the cover 11K of the case 11C, and the chassis 11 is installed so that it is sandwiched here. Next, the pair of hook units 13t provisioned on the arm units 13A and 13B of the installation member 13 engages with the pair of holes 11h provisioned in the interior side surface of the chassis 11 (inside the channel M11). At this time, as the chassis 11 is deeply sandwiched between each flange portion 13h, the installation member 13 is positioned deeply in the chassis 11, and the abutment surface 131 of the hook unit 13t lines up with the entrance side edge of the notch 114 (back surface side of the outer wall of the entrance side) to be installed to the chassis 11 at a position facing the chassis 11 toward the direction of installation (Z axis illustrated in FIGS. 1, 2A and 2B). In this way, the current path under test CB is disposed in a desirable position in the channel M11 of the chassis 11. Therefore, the positions between the multiple electromagnetic conversion elements 15 stored in the chassis 11 and the current path under test CB may be reliably determined

Also, when some load is applied on the current path under test CB, and the current path under test CB and the installation member 13 might be removed from the channel M11 of the chassis 11, the engagement between the hook unit 13t and the hole 11h as well as the sandwiching of the flange portion 13h deep within the chassis 11 prevents movement toward the surface of the chassis 11 and movement deeper in the chassis 11. Also, if force is applied externally from the chassis 11, the hook units 13t of the installation member 13 are engaged with the holes 11h within the channel M11 formed on the interior side of the chassis 11, and so the installation member 13 holding the current path under test CB is not readily removed from the chassis 11. As a result, by inserting the current path under test CB and the installation member 13 into the channel of the chassis 11, the current path under test CB may be easily disposed in a desired position, and the current path under test CB may also be reliably secured. Therefore, a current sensor 101 may be provided in which the current path under test CB is reliably secured disposed in a desirable position.

Also, the curved wall 13S corresponding to the outer edge of the cylindrically shaped current path under test CB spans at least 180°, and so the outer circumference of the current path under test CB is held contiguously along the curved wall 13S that spans at least 180°. For this reason, when some load is applied to the current path under test CB, and the current path under test CB and the installation member 13 might be removed from the channel of the chassis 11, the two arm units 13A and 13B are constrained by the interior surface formed by the channel M11 of the chassis 11, and so it is difficult to remove the current path under test CB from the portion enclosed in the curved wall 13S. Also, regarding the curved wall 13S, as the entrance point of the holding space is slightly narrower than the maximum diameter of the holding space, the current path under test CB inserted from the entrance point is not easily removed from the holding space, and may be reliably secured in the holding space. As a result, the current path under test CB may be disposed in a desirable position, and the current path under test CB may also be more reliably secured, which is achieved with a simple configuration.

Also, as the flange portion 13h extending in a direction (Z1 axis illustrated in FIG. 3A) along the chassis 11 (outer edge of the connection unit 13J) is provisioned on both side edges of the connection unit 13J, each flange portion 13h deeply sandwiches the chassis 11, and vertical movement (Y1-Y2 axis illustrated in FIG. 3A) of the installation member 13 in the chassis 11 may be controlled. As a result, removal of the installation member 13 from the channel M11 of the chassis 11 may be prevented. Further, minimizing the gap between the flange portions 13h and the chassis 11 prevents the installation member 13 from vibrating.

In contrast, the current sensor 101 is removed from the current path under test CB by moving the free edge side of the pair of arm units 13A and 13B exposed externally to the chassis 11 toward the inner side (closer together), which slightly flexes each arm unit 13A and 13B, and so the hook units 13t are moved in a direction to be removed from the holes 11h to disengage the hook units 13t from the holes 11h. Next, at this state, while sliding the installation member 13 relative to the chassis 11, the installation member 13 is removed from the channel M11 of the chassis 11. As illustrated in FIGS. 2A, 2B, 3A, and 3B, as a portion of the two arm units 13A and 13B, i.e. the distal side, is protruding from the chassis 11, so even if workers are wearing gloves for safety reasons, the installation member 13 may still be removed from the channel M11 of the chassis 11 using a simple configuration. Next, each of the arm units 13A and 13B of the installation member 13 are pushed open outward until the exit point of the holding space is wide enough for the portion of the current path under test CB at its maximum diameter to pass through, the current path under test CB is moved from the exit point outside the holding space, and then the outer portion of the installation member 13 is removed from between each of the arm units 13A and 13B. At this time, similar to the installation of the current path under test CB to the installation member 13, the connecting portions of the arms units 13A and 13B and the connection unit 13J are curved to allow the arm units 13A and 13B to flex out in an opposing direction that creates enough space for the current path under test CB to readily exit externally from the holding space, and so the current path under test CB may be readily removed from the installation member 13.

As previously described, the current sensor 101 according to the first Embodiment of the present invention, when the current path under test CB and the installation member 13 is disposed in the channel M11 of the chassis 11, the current path under test CB is securely supported in the channel M11 of the chassis 11, and at the same time the hook units 13t provisioned in the arms units 13A and 13B of the installation member 13 are engaged with the holes 11h provisioned on the interior surface forming the channel M11 of the chassis 11, and so if the current path under test CB and the installation member 13 might be removed from the channel M11 of the chassis 11, the engagement of the hook units 13t to the holes 11h prevent this movement. That is to say, as the hook units 13t and holes 11h are engaged, and the installation member 13 is installed to the chassis 11, the channel M11 and the installation member 13 together hold the current path under test CB, and so the engagement between the hook units 13t and the holes 11h control any movement caused by the current path under test CB and the installation member 13 being removed from the channel M11 of the chassis 11. As a result, by inserting the current path under test CB and the installation member 13 into the channel M11 of the chassis 11, the current path under test CB may be readily disposed in a desirable position, and at the same time, the current path under test CB may be reliably secured.

Particularly according to the present embodiment, as the installation member 13 is installed by being inserted into the channel M11 while the current path under test CB is held within the connection unit 13J and the pair of arm units 13A and 13B, the current path under test CB is held in the interior portion farthest from the outer portion of the chassis 11. For this reason, if force is applied externally to the chassis 11, the current path under test CB is not readily removed externally from the chassis 11, and the current path under test CB is reliably secured.

Also, when the installation member 13 is disposed in the channel M11 of the chassis 11, and the hook units 13t and the holes 11h are engaged, a portion of the two arm units 13A and 13B protrude from the chassis 11, and so by moving the arm units 13A and 13B toward the inner side, the hook units 13t are moved in a direction to be removed from the holes 11h to disengage the hook units 13t from the holes 11h. As a result, the installation member 13 may be removed from the channel M11 of the chassis 11, and the current path under test CB may be readily removed, which is achieved with a simple configuration.

Also, as the curved wall 13S that corresponds to the outer edge of the cylindrically shaped current path under test CB is formed to span at least 180° on the inner wall, after widening the two arm units 13A and 13B of the installation member 13 and setting the current path under test CB in the portion enclosed in the curved wall 13S, the current path under test CB is held by the curved wall 13S that spans at least 180°. For this reason, when disposing the installation member 13 at this state to the chassis 11, if the current path under test CB might be removed, the two arm units 13A and 13B are constrained by the interior surface forming the channel M11 of the chassis 11, and so it difficult for the current path under test CB to become removed from the portion enclosed in the curved wall 13S. As a result, the current path under test CB may be disposed in a desirable position, and the current path under test CB may also be more reliably secured, which is achieved with a simple configuration.

Also, as the flange portions 13h are provisioned on the side ends of the connection unit 13J to extend in a direction along the chassis 11, the chassis 11 is sandwiched between the flange portions 13h, which prevents the installation member 13 from moving vertically in the chassis 11. As a result, this prevents the installation member 13 from being removed from the chassis M11 of the chassis 11. Further, minimizing the gap between the flange portion 13h and the chassis 11 prevents the installation member 13 from vibrating.

Also, as the notch 13K is provisioned in the flange portions 13h, this notch 13K acts as the buffer portion, which allows the shape of the flange portion 13h to be readily deformed. As a result, the arm units 13A and 13B of the installation member 13 may be readily opened, and the current path under test CB may be easily set in the portion enclosed in the curved wall 13S.

Also, as multiple electromagnetic conversion elements 15 are arranged on the virtual ellipse IS1 centered around the current path under test CB, the detection values from each electromagnetic conversion element 15 may be added together. As a result, a small misalignment of the position of the current path under test CB is unlikely to decrease measurement accuracy.

### Second Embodiment

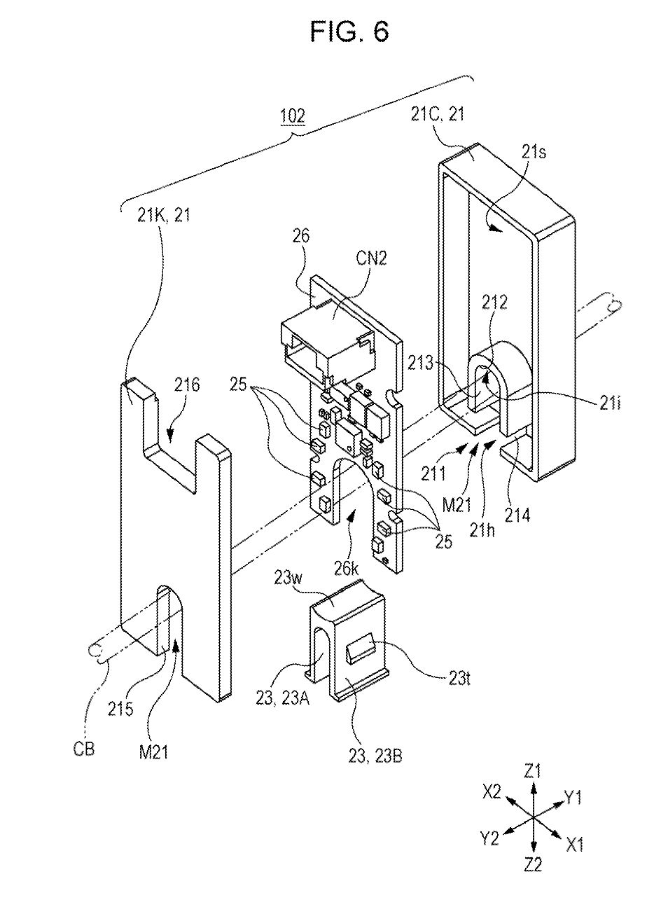

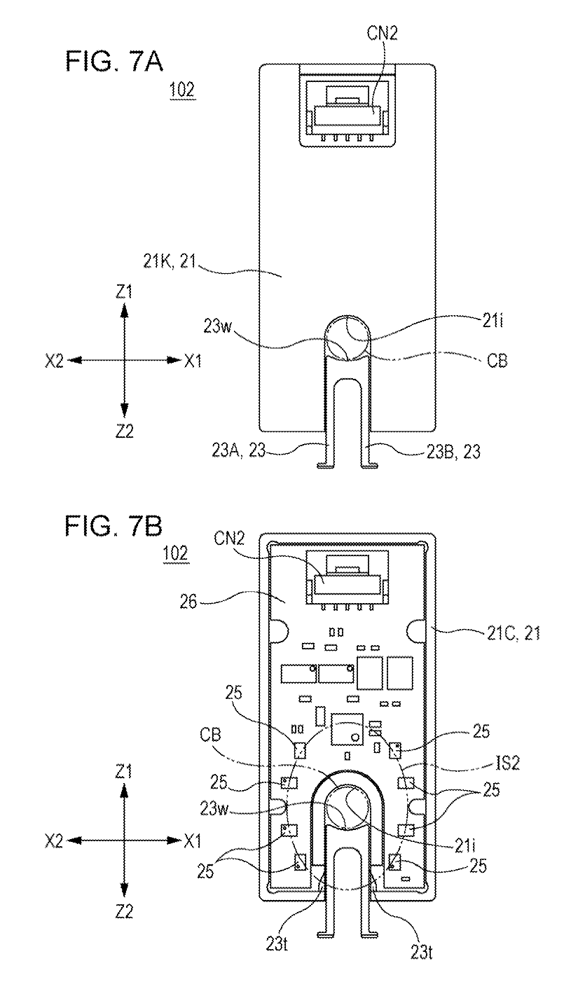

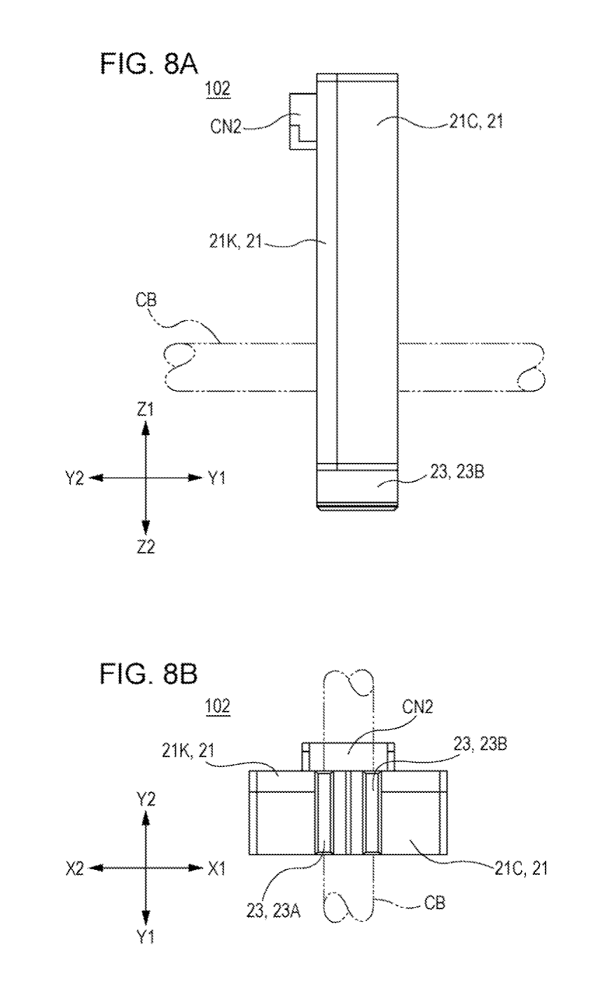

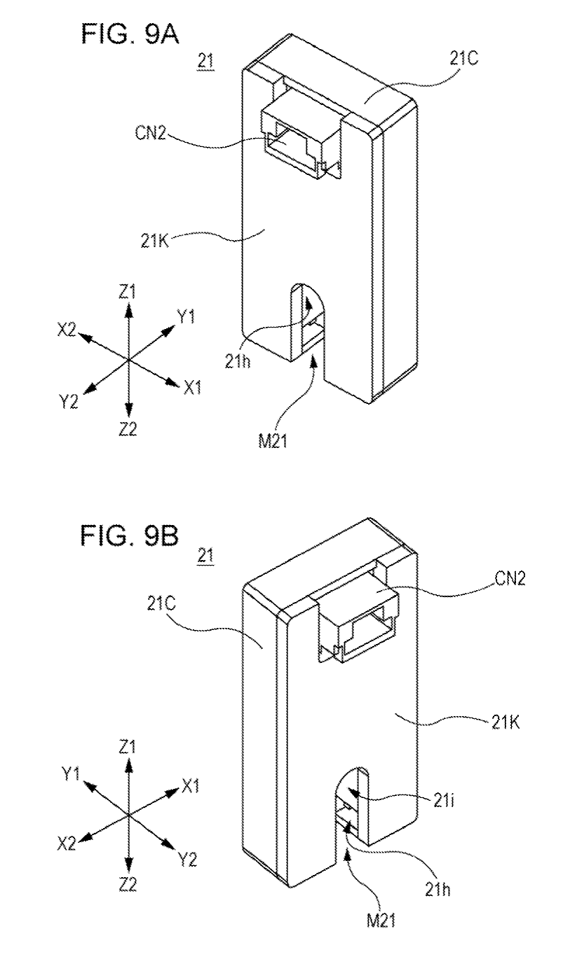

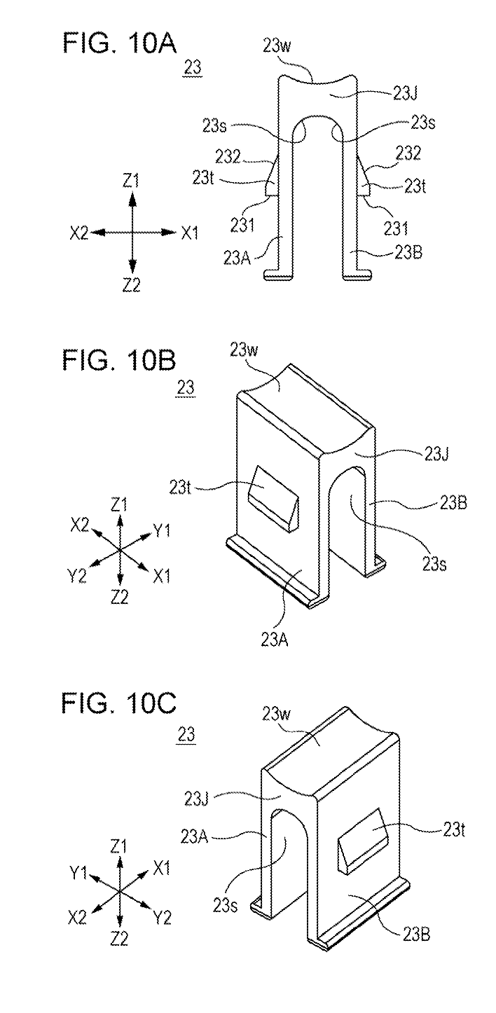

FIG. 6 is an exploded perspective view illustrating a current sensor 102 related to the second Embodiment of the present invention. FIGS. 7A and 7B are diagrams describing the current sensor 102 related to the second Embodiment, in which FIG. 7A is a front view diagram seen from the Y2 side illustrated in FIG. 6, and FIG. 7B is the front view diagram illustrated in FIG. 7A with a cover 21K removed. FIGS. 8A and 8B are diagrams describing the current sensor 102 related to the second Embodiment, in which FIG. 8A is a side view diagram seen from the X1 side illustrated in FIG. 6, and FIG. 8B is a bottom view diagram seen from the Z2 side illustrated in FIG. 6. FIGS. 9A and 9B are diagrams describing a chassis 21 of the current sensor 102 related to the second Embodiment, in which both FIGS. 9A and 9B are perspective view diagrams of the chassis 21 seen at different angles. FIGS. 10A through 10C are diagrams describing an installation member 23 of the current sensor related to the second Embodiment, in which FIG. 10A is a front view diagram of the installation member 23 seen from the 2 side illustrated in FIG. 6, and FIGS. 10B and 10C are perspective view diagrams of the installation member 23 seen at different angles.

As illustrated in FIGS. 6 through 8B, the current sensor 102 includes multiple electromagnetic conversion elements which detect magnetism generated when a current flows through the current path under test CB, a chassis 21 having a channel M21 in which the current path under test CB is disposed, and an installation member 23 which can be fixed to the chassis 21. Also, the current sensor 102 includes a wiring board 26 stored in a storage unit 21s of the chassis 21, and a connector CN2 having an extraction terminal (not illustrated) to extract electrical signals from the electromagnetic conversion elements 25 installed on the wiring board 26.

As illustrated in FIGS. 6, 7A, 7B, 9A, and 9B, the chassis 21 is configured with a case 21C formed as a box with an opening on one side that stores a wiring board 26 to which multiple electromagnetic conversion elements 25 are installed, and a cover 21K to cover the case 21C on the opening side. A channel M21 in the chassis 21 is formed in a U-shape (concave form) such that the chassis 11 is cut from one end toward the center. The channel M21 is configured to be disposed with the installation member 23 and the current path under test CB. Also, the interior surface (interior circumference surface) of the chassis 21, which forms the channel M21, is provisioned with a hole 21H on each right and left side to engage a hook unit 23t of the installation member 23, which is described later. Further, an interior wall surface 21i of the chassis 21 that forms the bottom of the channel M21 is formed in a curved shape. Here, the bottom of the channel M21 is the portion of the interior wall surface 21i that is nearest to the interior side (center side) of the chassis 21, and represents the portion of the interior wall surface 21i that meets the distal portion of the installation member 23 that is inserted into the channel M21. This interior wall surface 21i is formed having a form complementary to the form of the outer circumference of the current path under test CB.

The chassis 21 may be formed using synthetic plastic materials such as ABS (acrylonitrile butadiene styrene), PET (polyethylene terephthalate), PBT (polybutylene terephthalate), or LCP (liquid crystal polymer). Use of synthetic plastic materials enables the chassis 21 to be readily manufactured by injection molding or other technique.

The case 21C is formed as a box with an opening on one side, and also with a storage unit 21s that may internally store the wiring board 26. Also, a depression unit 211 is formed by cutting the case 21C from one end toward the center. This depression unit 211 is formed at a size large enough to store the installation member 23. A rearward wall 212 of the depression unit 211 is formed with a curve that corresponds to the outer circumference surface of a current path under test CB. That is to say, the rearward wall 212 is formed having a form complementary to the outer circumference of the current path under test CB, and by covering the opening of the case 21C with the cover 21K, the interior wall surface 21i of the chassis 21, described later, is configured with the rearward wall 212 and a rearward portion of the depression unit 215 of the cover 21K. Also, an interior wall 213 connected to both ends of the rearward wall 212 is formed in parallel separated with just enough distance to store a pair of arms units 23A and 23B of the installation member 23. A pair of notches 214 for installing the installation member 23 is formed in each interior wall 213 at a position so that they are facing each other. Each notch 214 is provisioned near the entrance of the depression unit 211, and is formed so that the case 21C is cut vertically from the opening of the case 21C toward the direction of the storage surface side of the storage unit 21s (bottom portion). According to the present embodiment, each notch 214 is formed in a side flange form at opposing positions that connects to the outer wall of the entrance. This notch 214 configures the hole 21H previously described by closing the opening of the case 21C with the cover 21K.

The cover 21K The cover 11K is formed with laminate materials, and a depression unit 215 is formed on one edge with the same form as that of the depression unit 211 of the case 21C. That is to say, the depression unit 215 of the cover 21K is similar to the depression unit 211 of the case 21C in that it is formed at a size large enough to store the installation member 23. The depression unit 215 formed in this cover 21K and the depression unit 211 of the same form formed in the case 21C together form the channel M21 previously described. Also, an opening 216 is formed on the edge formed by the depression unit 215 of the cover 21K and the edge on the opposing side to expose a portion of a connector CN2 externally from the chassis 21.

The wiring board 26 may be formed, for example, using a generally well-known double-sided printed wiring board, in which copper (Cu) or some other metallic foil is patterned on the base board, which is formed from glass mixed with epoxy resin, to form the wiring pattern. The wiring board 26 is formed having a form complementary to the storage surface (bottom surface) of the storage unit 21s, and a notch 26K is formed having a form complementary to the depression unit 211 of the case 21C. The interior wall 213 of the case 21C previously described is sandwiched in this notch 26K, and the current path under test CB is inserted here. As illustrated in FIGS. 6 and 7B, multiple electromagnetic conversion elements 25(8 in FIG. 7B) are installed near the notch 26K of the wiring board 26. According to the present embodiment, a printed wiring board formed from glass mixed with epoxy resin is used for the wiring board 26, but this is not specifically limited, and so a rigid board with insulating properties may be used, for example, or a ceramic wiring board may also be used.

The electromagnetic conversion element 25 is a current sensor element that detects magnetic fields generated when current flows through the current path under test CB, and may use, for example, a magnetic detection GMR element that has a giant magneto resistive property. Though details are not illustrated for simplification of the description, this electromagnetic conversion element 25 is configured by manufacturing the GMR element onto a silicon substrate, and then using thermoset synthetic plastic to package the chip that has been cut out, and a lead terminal to extract signals is electrically connected to the GMR element. Also, the device is then soldered to the wiring board 26, described later, by this lead terminal.

As illustrated in FIG. 6 and FIG. 7B, the eight units of the electromagnetic conversion element 25 are disposed by being sandwiched between the wiring board 26 and the notch 26K. According to the present embodiment and as illustrated in FIG. 7B, when the current path under test CB is disposed in the channel M21 of the chassis 21 discussed later, the eight units of the electromagnetic conversion element 25 are disposed on a virtual ellipse IS2 centered around the current path under test CB. As a result, the detection values from each electromagnetic conversion element 25 may be added together, and so a small misalignment of the position of the current path under test CB is unlikely to decrease measurement accuracy.

As illustrated in FIG. 6 through FIG. 10C, the installation member 23 is configured with two arm units 23A and 23B, and a connection unit 23J that connects and supports movement of the two arm units 23A and 23B. Specifically, the installation member 23 is formed roughly in a U shape, and is configured with a pair of arm units 23A and 23B formed as long plates, and the connection unit 23J to which a portion of each arm unit 23A and 23B is connected. The installation member 23 is formed at a size large enough to be inserted in the channel M21 of the chassis 21. This installation member 23 is formed using synthetic plastic materials such as ABS (acrylonitrile butadiene styrene), PET (polyethylene terephthalate), PBT (polybutylene terephthalate), or LCP (liquid crystal polymer). Use of synthetic plastic materials enables the installation member 23 to be readily manufactured by injection molding or other technique.

The pair of arm units 23A and 23B extend in parallel from both ends of the connection unit 23J. Specifically, the connecting portions of the arms units 23A and 23B and the connection unit 213J are configured with a curvature that allows the arm units 23A and 23B to flex in an opposing direction that creates enough space for the current path under test CB to enter and pass through the channel M21 toward the installation member 23. Also as illustrated in FIGS. 6, 7B, 10A, 10B, and 10C, the hook unit 23t is formed on the outer side of both arms units 23A and 23B. Specifically, the hook unit 23t is formed on the outer surface of each arm unit 213A and 23B, and protrudes outward. As previously described, this pair of hook units 23t is configured to engage with each hole 21H provisioned on the interior surface (interior wall 213) of the chassis 21 that forms the channel M21. Regarding the outer surface of the arm units 23A and 23B, each hook unit 23t is formed at a position so that the free end side of the arms units 23A and 23B are exposed externally from the chassis 21 when installed to the chassis 21. The exposed portions of the arm units 23A and 23B are used to install and remove the current path under test CB to/from the installation member 23, and to install and remove the installation member 23 to/from the chassis 21. Also, each hook unit 23t is formed to extend outward toward the free end side of the arm units 23A and 23B, and is configured with an abutment surface 231 that extends vertically regarding the formed surface of the hook unit 23t of the arms units 23A and 23B, and a diagonal surface 232 that connects with this abutment surface 231 (refer to FIG. 10A). This abutment surface 231 of the hook unit 23t secures the installation member 23 to the chassis 21 by the abutment to the entrance end face of the notch 214 formed on the interior wall 213 of the case 21C (for the present embodiment, this is the outer wall of the entrance side), at a state positioned in the direction of the formed channel M21 (Z axis illustrated in FIGS. 6, 7A, and 7B).

Also as illustrated in FIGS. 10A, 10B, and 10C, an exterior wall surface 23W of the connection unit 23J is formed in a curved form. Specifically, the exterior wall surface 23 is curved to indent toward the free end side of the arm units 23A and 23B. For this reason, when the installation member 23 is installed to the chassis 21, a cylindrical space is formed between the interior wall surface (rearward wall) 21i of the chassis 21 that forms the bottom of the channel M21 previously described and this exterior wall 23W. That is to say, a holding space is formed having a form complementary to the outer circumference form of the current path under test CB, by the interior wall surface 21i of the chassis 21 (rearward wall of the case 21C) and the exterior wall surface 23W of the connection unit 23J. One side of the outer circumference of the current path under test CB (rearward side) touches the interior wall surface 21i of the chassis 21, and the other side of the outer circumference of the current path under test CB (entrance side) touches the exterior wall surface 23W of the connection unit 23J, and so the current path under test CB is held in the holding space. That is to say, the current path under test CB is held by being sandwiched between the interior wall surface 21i of the chassis 21 and the exterior wall surface 23W of the connection unit 23J (installation member 23). As a result, the current path under test CB is reliably held at a state where the current path under test CB abuts (touches) contiguously corresponding to the interior wall surface 21i of the chassis 21 (rearward wall of the channel M21) and the exterior wall 23W of the connection unit 23J.

The following describes an example procedure (method) to install and remove the current sensor 102 configured as previously described to/from the current path under test CB.

First, the current path under test CB is inserted into the channel M21 of the chassis 21, and then the current path under test CB is pushed against the interior wall surface 21i of the chassis 21 forming the base of the channel M21, so as to be disposed in the channel M21. At this time, as the interior wall surface 21i is formed having a form complementary to the outer circumference form of the current path under test CB, the curved surface of the interior wall surface 21i and the outer edge (outer circumference) of the current path under test CB abut over a wide region.

Next, the channel M21 of the chassis 21 and the connection unit 23J of the installation member 23 are set to face each other, and as the installation member 23 is slid relative to the chassis 21, the installation member 23 is installed so that it fits into the channel M21 of the chassis 21. At this time, the free end sides of the pair of arms units 23A and 23B exposed externally from the chassis 21 are flexed in a direction so that they become close to each other until each flange portion 23H of the installation member 23 is positioned between the interior wall 213 of the channel M21, and then the installation member 23 is inserted into the channel M21. The connecting portions of the arms units 23A and 23B and the connection unit 23J are configured with a curvature that allows the arm units 23A and 23B to flex in an opposing direction that creates enough space for the installation member 23 to enter the channel M21 of the chassis 21. Also, the hook units 23t provisioned on the arm units 23A and 23B of the installation member 23 engage with the holes 21H provisioned on the interior surface of the chassis 21. At this time, the current path under test CB is sandwiched in the cylindrical holding space formed between the interior wall surface 21i of the chassis 21 and the exterior wall surface 23W of the installation member 23 (connection unit 23J). As a result, the current path under test CB is disposed in a desirable position in the channel M21 of the chassis 21. Therefore, the positioning of the multiple electromagnetic conversion elements 25 stored in the chassis 21 in relation to the current path under test CB may be reliably performed.

Also, when some load is applied on the current path under test CB, and the current path under test CB and the installation member 23 might be removed from the channel M21 of the chassis 21, the engagement between the hook units 23t and the holes 21H prevents this movement. Also, if force is applied externally from the chassis 21, the hook units 23t of the installation member 23 are engaged with the holes 21H within the channel M21 formed on the internal side of the chassis 21, and so the current path under test CB sandwiched between the interior wall surface 21i of the chassis 21 and the exterior wall surface 23W of the installation member 23 in the channel M21 is not removed externally from the chassis 21. As a result, by inserting the current path under test CB and the installation member 23 into the channel M21 of the chassis 21, the current path under test CB may be easily disposed in a desired position, and the current path under test CB may also be reliably secured. Therefore, a current sensor 102 may be provided in which the current path under test CB is reliably secured disposed in a desirable position.

Also, a cylindrical space is formed between the interior wall surface (rearward wall) 21i of the chassis 21 that forms the bottom of the channel 21 and the exterior wall surface 23W of the connection unit 23J of the installation member 23. For this reason, particularly when holding a cylindrically shaped current path under test CB, the outer edge of the current path under test CB is supported by the curved face form of the interior wall surface 21i and the exterior wall surface 23w, and so the current path under test CB may be disposed in a more desirable position.

In contrast, the current sensor 102 is removed from the current path under test CB by moving the free edge side of the pair of arm units 23A and 23B exposed externally to the chassis 21 to the internal side (closer together), slightly flexing each arm unit 23A and 23B, and so the hook units 23t are moved in a direction to be removed from the holes 21H to disengage the hook units 23t from the holes 21H. Next, at this state, while sliding the installation member 23 relative to the chassis 21, the installation member 23 is removed from the channel M21 of the chassis 21. As illustrated in FIGS. 7A, 7B, 8A, and 8B, as a portion of the two arm units 23A and 23, i.e. the distal side, is protruding from the chassis 21, if workers are wearing gloves for safety reasons, the installation member 23 may still be removed from the channel M21 of the chassis 21 using a simple configuration.

As previously described, according to the current sensor 102 in the second Embodiment of the present invention, when the current path under test CB and the installation member 23 is disposed in the channel M21 of the chassis 21, the current path under test CB is securely supported in the channel M21 of the chassis 21, and at the same time the hook units 23t provisioned in the arms units 23A and 23B of the installation member 23 are engaged with the holes 21H provisioned on the interior surface forming the channel M21 of the chassis 21, and so if the current path under test CB and the installation member 23 might be removed from the channel M21 of the chassis 21, the engagement of the hook units 23t to the holes 21H prevents this movement. That is to say, as the hook units 23t and holes 21H are engaged, and the installation member 23 is installed to the chassis 21, the channel M21 and the installation member 23 together hold the current path under test CB, and so the engagement between the hook units 23t and the holes 21H control any movement caused by the current path under test CB and the installation member 23 being removed from the channel M21 of the chassis 21. Particularly according to the present embodiment, as the current path under test CB is held by being sandwiched between the interior wall surface 21i of the channel M21 and the exterior wall surface 23W of the connection unit 23J, the current path under test CB may be reliably secured. As a result, by inserting the current path under test CB and the installation member 23 into the channel M21 of the chassis 21, the current path under test CB may be readily disposed in a desirable position, and at the same time, the current path under test CB may be reliably secured.

Also, when the installation member 23 is disposed in the channel M21 of the chassis 21, and the hook units 23t and the holes 21 are engaged, a portion of the two arm units 23A and 23B protrude from the chassis 21, and so by moving the arm units 23A and 23B internally, the hook units 23t are moved in a direction to be removed from the holes 21H to disengage the hook units 23t from the holes 21H. As a result, the installation member 23 may be removed from the channel M21 of the chassis 21, and the current path under test CB may be readily removed, which is achieved with a simple configuration.

Also, as a cylindrical space is formed between the interior wall surface 21i of the chassis 21 that forms the bottom of the channel M21 and the exterior wall 23W of the connection unit 23J of the installation member 23, the current path under test CB may be disposed in this space. For this reason, the current path under test CB may be sandwiched between the interior wall surface 21i and the exterior wall surface 23W, and when the installation member 23 is disposed in the chassis 21, the current path under test CB is not likely to be removed from the channel M21 portion of the chassis 21 due to the installation member 23 in a case where the current path under test CB might be removed. As a result, the current path under test CB may be more reliably secured, which is achieved with a simple configuration. Particularly when the current path under test CB has a cylindrical shape, the curved form of the interior wall surface 21i and the exterior wall surface 23W enables the outer edge of the current path under test CB to be supported, and so the current path under test CB may be disposed in a more desirable position.

Also, as multiple electromagnetic conversion elements 25 are arranged on the virtual ellipse IS2 centered around the current path under test CB, the detection values from each electromagnetic conversion element 25 may be added together. As a result, a small misalignment of the position of the current path under test CB is unlikely to decrease measurement accuracy.

The present invention is not limited to the embodiments previously described, and the following describes different modifications as examples of other embodiments that may be implemented, and these embodiments fall under the technical scope of the present invention.

### First Modification

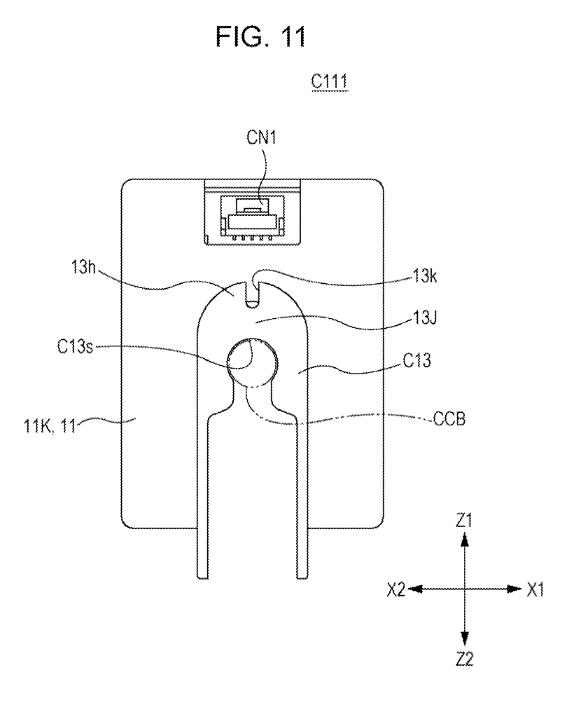

FIG. 11 is a diagram that describes a first Modification of the current sensor 101 related to the first Embodiment, and is a front view diagram of a current sensor C111. As illustrated in FIG. 11, the installation member 13 of the previously described first Embodiment may be replaced with an installation member C13 including a curved wall C13S corresponding to the outer edge of a current path under test CCB that has a small outer diameter. That is to say, the curved wall C13S is an interior wall of the installation member 13 near the connection unit 13J that has a thickness formed to match with the outer circumference form of the current path under test CCB with a small outer diameter, and so is configured in a form that corresponds to the outer circumference form of the current path under test CCB. As a result, by using the installation member C13 with the curved wall C13S that has a small radius of curvature and sharing other parts as well, the current sensor C111 may be manufactured that is also applicable to the current path under test CCB with a small outer diameter. Of course this means that a current sensor may be manufactured to support a current path under test with a large diameter as well, and thus various types of current paths under test may be supported. That is to say, by adjusting the thickness of the interior wall of the installation member 13, a curved wall corresponding to current paths under test of different diameter dimensions may be formed.

### Second Modification

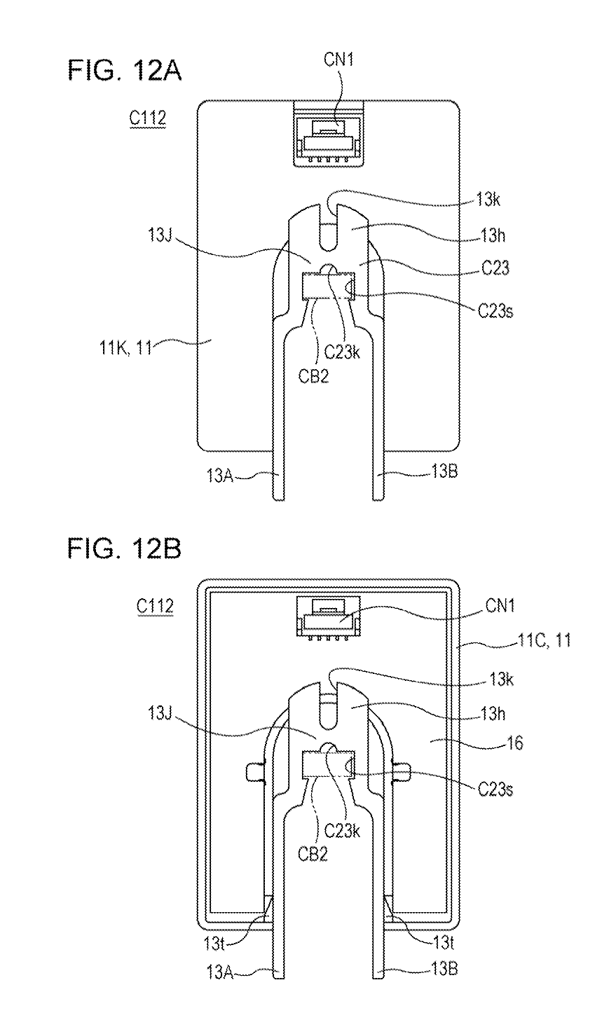

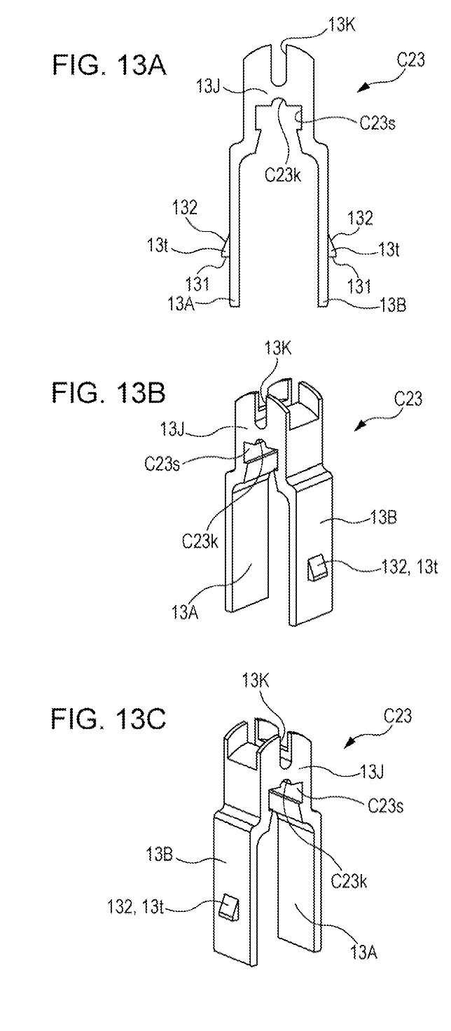

FIGS. 12A and 12B are diagrams describing the second Modification of the current sensor 101 related to the first Embodiment. FIG. 12A is a front view diagram of a current sensor C112, and FIG. 12B is the front view diagram illustrated in FIG. 12A with the cover 11K removed. FIGS. 13A through 13C are diagrams describing an installation member C23 of the current sensor C112 related to the first Embodiment, in which FIG. 13A is a front view diagram seen from the Y2 side illustrated in FIG. 1, and FIGS. 13B and 13C are perspective view diagrams of the installation member seen at different angles.

The current sensor C112 illustrated in FIGS. 12A, 12B, 13A, 13B, and 13C includes an interior wall C23S of the installation member C23 that includes the connection unit 13J, and this interior wall C23S is configured in a form complementary to the outer circumference form of a current path under test CB2 having a rectangular cross-sectional form. That is to say, the interior wall C23S is formed having a form complementary to the outer diameter form of the current path under test CB2 held in the holding space at a state where the entrance (and exit) point corresponding to the space to be used by the current path under test CB2 (holding space) is secured. Similar to the curved wall C13S related to the first Modification previously described, by adjusting the thickness of the installation member C23 near the connection unit 13J to match the outer circumference form of the current path under test CB2 (rectangular form), the installation member C23 is configured having a rectangular form corresponding to the outer circumference form of the current path under test CB2. As a result, when holding the current path under test CB2 with a rectangular form, the current path under test CB is reliably held in the holding space with a rectangular form at a state where the interior wall C23S of abuts (touches) contiguously regarding the outer circumference of the current path under test CB2. Particularly by forming the interior wall C23S of the installation member C23 to correspond to the outer circumference form of the current path under test CB2, which is the object to be held, the chassis 11 does not have to be changed, and so by replacing with the installation member C23, the installation member C23 and the current path under test CB2 may be held in the chassis 11.

Also, a depression unit C23K cut toward the rearward wall of the channel M11 is formed on the rearward surface of the interior wall C23S (side facing the entrance point of the holding space). This depression unit C23K is formed to face the notch 13K formed in the flange portion 13h centrally positioned on the rearward surface of the interior wall C23S. As a result, when removing the installation member C23 from the chassis 11, the depression unit C23K acts as the buffer allowing the interior wall C23S to deform, and this enables the arm units 13A and 13B of the installation member C23 to be readily closed. That is to say, when the installation member C23 is installed to the chassis 11, the notch 13K formed on the flange portion 13h acts as a buffer that allows the flange portion 13h to be readily deformed, and in contrast when removing the installation member C23 from the chassis 11, the depression unit C23K acts as a buffer that allows the interior wall C23S to be readily deformed. As a result, this works together with the flexure of the arm units 13A and 13B to enable installation and removal of the installation member C23 to/from the chassis 11 to be more readily performed.

### Third Modification

According to the first Embodiment described previously, it was preferable to provision the flange portion 13h in the configuration, but the flange portion 13h may be omitted. Also, the flange portion 13h was preferably configured with the notch 13K, but the notch 13K may also be omitted.

### Fourth Modification

According to the previously described embodiment, the configuration included an arrangement of eight units of the electromagnetic conversion element 25, but this is not limited to only eight units, a configuration of two, four, six, or any number of units of the electromagnetic conversion element 25 may be configured.

### Fifth Modification

According to the previously described embodiments, the configuration included an arranged of the electromagnetic conversion elements 25 on the virtual ellipses IS1 and IS2, but this is not limited to the virtual ellipses IS1 and IS2, the configuration may be arranged on a square form, or on a virtual orbit with a depressed center, for example.

### Sixth Modification

According to the previously described embodiments, GMR elements were preferably used for the electromagnetic conversion elements (15 or 25), but any electromagnetic detection element that may detect the magnetic direction may be used, such as an MR (magneto resistive) element, an AMR (anisotropic magneto resistive) element, a TMR (tunnel magneto resistive) element, or an electron hole element. However, when using an electron hole element, the sensitivity axis is different from that of the GMR element and MR element, the configuration has to be designed to accommodate the sensitivity axis of the electron hole element to be used.

The present invention is not limited to the embodiments previously described, and modifications may be made that do not deviate from the scope of the present invention.

1. A current sensor, comprising:
a plurality of electromagnetic conversion elements configured to detect a magnetic field applied thereto when a current flows through a current path under test;
a chassis configured to accommodate the electromagnetic conversion elements, the chassis having an inner wall forming a groove; and
an installation member configured to hold the current path under test and be installed in the groove;
wherein the installation member includes:
a pair of arm units each having a hook unit protruding toward the inner wall; and
a connection portion connecting the pair of arm units;
and wherein the inner wall of the chassis has cutouts configured to engage with the hook units.

2. The current sensor according to claim 1, wherein the arm units are capable of bending inwardly while the current path under test is being held by the arm units and an inner side of the connection portion.

3. The current sensor according to claim 1, wherein an inner wall of the connection portion includes a curved wall that spans at least 180° corresponding to an outer edge of the current path under test which has a cylindrical shape.

4. The current sensor according to claim 1, wherein the inner interior wall of the connection portion has a shape complementary to an outer circumference of the current path under test which has a rectangular cross-section.

5. The current sensor according to claim 4, wherein the connection portion has a concave formed on the inner wall thereof.

6. The current sensor according to claim 3, further comprising:
a flange portion provided on the connection portion so as to clamp the chassis.

7. The current sensor according to claim 6, wherein the flange portion has a notch.

8. The current sensor according to claim 1, wherein the current path under test is held between the inner wall forming the groove and an outer wall of the connection portion.

9. The current sensor according to claim 8, wherein the inner wall that forms a bottom of the groove has a first curved surface, and the outer wall of the connection portion has a second curved surface, the first and second curved surfaces forming a space between the inner wall of the groove and the outer wall of the connection portion when the installation member is disposed in the groove and the hook units are engaged with the cutouts.

10. The current sensor according to claim 1, wherein a portion of the arm units protrude from the chassis when the installation member is installed in the groove such that the hooks units engage with the cutouts.

11. The current sensor according to claim 1, wherein the plurality of electromagnetic conversion elements are arranged on a virtual ellipse centered around the current path under test when the current path under test is held in the installation member disposed in the groove.
